(19) United States
(12) Patent Application Publication
(10) Pub. No.: US 2015/0318449 A1
(43) Pub. Date: Nov. 5, 2015

(54) A hermetically sealed optoelectronic component

(71) Applicant: Lumichip Limited, Hong Kong (HK)

(72) Inventors: Juha Rantala, Hong Kong (HK); Pekka Katila, Espoo (FI)

(21) Appl. No.: 14/649,226

(22) PCT Filed: Dec. 2, 2013
(86) PCT No.: PCT/FI2013/051121

§ 371 Date: Jun. 3, 2015

Related U.S. Application Data
(60) Provisional application No. 61/732,432, filed on Dec. 3, 2012.

(30) Foreign Application Priority Data
Dec. 3, 2012 (FI) 20126259

(51) Int. Cl. H01L 33/48; H01L 25/075; H01L 33/50; H01L 33/64; H01L 33/00; H01L 33/32

(52) U.S. Cl. CPC H01L 33/486; H01L 33/0075; H01L 33/32; H01L 33/507; H01L 33/644; H01L 25/0753

(57) ABSTRACT

This invention provides inexpensively hermetically packaged optoelectronic chips. Multiple similar or dissimilar optoelectronic chips can be produced according to the present methods. Additionally, the chips may include a heat sink for efficient thermal management and elements for wavelength conversion without compromising their efficiency or quality. Furthermore, optical structures are provided to allow optimization of optical performance.

### FIELD OF INVENTION

The present invention generally relates to the field of electronic packaging and in particular to the packaging of optoelectric devices, e.g. LEDs, Superluminescent LEDs (SLED), Laser Diodes (LD), or semiconductor detectors. More particularly, embodiments of the present invention include hermetically sealed packaging, e.g. a hermetically sealed LED light engine assembly.

### BACKGROUND OF THE INVENTION

In typical modern semiconductor production electronics are produced in a wafer format. A wafer can carry from a few units to thousands of individual units or chips. Typically, physical manufacturing of electronic chips stops in a chip singulation and packaging step, or in a wafer level packaging (WLP) step.

In typical WLP all chips contained on one wafer are packaged in a parallel fashion. However, this approach is not suitable for the packaging of LEDs or LDs for optical modules with multiples LEDs or LDs. This is due, in part, because WLP packaging does not allow flexible changes in chips as it is based on fixed mask sets and lithographic processing. Another disadvantage of WLP is that the phosphors commonly used for wavelength conversion for white light LEDs cannot be deposited or included easily in a WLP type package.

Particular challenges, for example with LED chip packaging, arise from high thermal load and optical requirements. A typical LED chip used for lightning purposes can dissipate several watts of power from an area of few square millimeters, and a module consisting of for instance tens of such units creates a thermal load that needs an efficient cooling solution.

Typically with modules for lightning applications and/or illumination the light output should be maximized with an appropriate optical structure which commonly includes a Wavelength Conversion Layer (WLC) layer, e.g. a phosphor layer, for white light generation. In high power LED modules heat dissipation is problematic as it degrades the wavelength conversion material properties and also, as is the case with phoshor materials, the conversion efficiency. Typically, the efficiency drops several percentage units if conversion material heats up from even 50 to 100 deg C.

Furthermore, electronic components are often highly sensitive to oxygen and moisture. To increase the reliability of the components, a hermetic sealing is preferred in many cases. Applications that benefit from hermetic sealing can be found in consumer products such as mobile phones and industrial cameras based on CMOS image sensors.

A purpose of hermetic sealing is to provide longer component lifetime. Hermetic sealing can substantially increase the mean time to failure as typical failure mechanisms are related to moisture leaking into the package corroding the contacts or active areas e.g. the facets of the laser diodes, as oxidation of component materials is a typical root cause of device failures.

Typical packaging of LEDs is based on epoxy sealing techniques. A commonly used example of manufacture lightning device is presented for example in U.S. Pat. No. 8,058,659. Encapsulation with resins is also possible. Such materials are presented, for example, in US 2006/0022356. However, these types of sealed structures provide only moderate levels of hermetic sealing as these materials are still permeable. Elevated temperatures during storage or device operation will accelerate moisture and gas diffusion through the epoxy encapsulation eventually leading to device failure. Adhesion layers between the substrate and the epoxy encapsulation are less reliable and may contain microchannels leading to leakages.

The invention offers advantages over wafer-level chip scale packaging (WLCSP), in which technique the whole wafer is package at once, and can also provide a means for hermetic sealing. With WLCSP technique one packaged component could carry one or more chips or emitting units such as LEDs. However it is recognized that in the case of packaging several units at the same time at the wafer level the functionality of all such LEDs is not guaranteed unless the wafer carrying the units has a 100% yield.

### SUMMARY OF THE INVENTION

It is an object of the present invention to provide a hermetically sealed optoelectronic component.

It is an aspect of certain embodiments to provide an optoelectronic component comprising; a substrate, at least one light emitter component mounted on the substrate, a spacer, and a transparent covering mounted on the spacer opposite the substrate.

The spacer can be mounted on a first surface of the substrate and surround the light emitter component, said spacer generally having a height greater than the light emitter component.

According to certain embodiments the spacer should be hermetically sealed to the first surface of the substrate and to the transparent covering. A hermetically sealed space is therefore formed which contains the light emitter component. The hermetically sealed space is thus defined by the substrate, the spacer and the transparent covering.

The hermetically sealed space can be essentially in a vacuum, in particular, wherein the pressure is between 0.1 mTorr to 100 mTorr. The hermetically sealed space can also, or alternatively be at least partially filled with a gas.

According to certain embodiments an active heat dissipating chip is disclosed which can be mounted directly on a heat sink. This provides enhanced thermal cooling characteristics.

Embodiments of the present invention aim to solve issues associated with multichip modules and their hermetic sealing in a cost effective way. A common problem in packaging is that the layouts and dimensions of the units or chips to be packaged are changing due to rapid technical advancement and process changes, as in the field of LED, SLED and LD technology. A flexible packaging approach is thus required that can accommodate frequently changing units without being modified despite changes in the actual LED processing or LED chips. An approach that is cost effective and, for example, which does not apply fixed mask sets is desired.

Glass-frit techniques are well suited for this task. A glass-frit method can be applied with different substrates and transparent covering materials. A benefit of the presented encapsulation scheme is the flexibility to manufacture low cost but high quality wavelength conversion layers such as phosphor layers on the top or bottom surface, or within a transparent covering.

Another benefit of hermetic packaging is that very low leak rates, <1E-8 atmcc/s will offer the potential to shorten the time used for lifetime reliability testing in certain applications. A leakage rate level of 1E-9 is achievable at least with the present glass-frit encapsulation method.

The flexibility of the present invention has a substantial advantage over other packaging methods such as WLP.

It is a further object of the present invention to provide a method for manufacturing a hermetically sealed optoelectronic component according to the present disclosure.

### BRIEF DESCRIPTION OF THE DRAWINGS

FIG. 1 is a perspective and cut-away view of a component having a rectangular spacer according to an embodiment of the present invention.

FIG. 2 is a perspective and cut-away view of a component having a circular spacer according to an embodiment of the present invention.

FIG. 3 is a perspective and cut-away view of the component of FIG. 1 having a heat sink attached.

FIG. 4 is a perspective and cut-away view of the component of FIG. 2 having a heat sink attached.

FIG. 5 is a flow diagram of an example method of manufacturing a component according to an embodiment of the present invention.

### DETAILED DESCRIPTION OF EXEMPLARY EMBODIMENTS

Described herein is a hermetically sealed optoelectronic component. According to an embodiment, there are optoelectronic components comprising; a substrate, at least one light emitter component mounted on the substrate, a spacer, and a transparent covering mounted on the spacer opposite the substrate.

Examples of optoelectronic components are Light Emitting Diode (LED) components, Laser Diode (LD) components, Superluminescent LEDs (SLED), and other non-emitting types of components such as semiconductor detectors. Similarly, examples of light emitter components are LED's, SLED's, LD's etc. Light emitter components according to the present invention should not be limited to those emitting visible light but also include other forms of electromagnetic radiation. Further examples of light emitter components include those which comprises an In-, Ga-, and/or N-containing compound, for instance an InGaN diode.

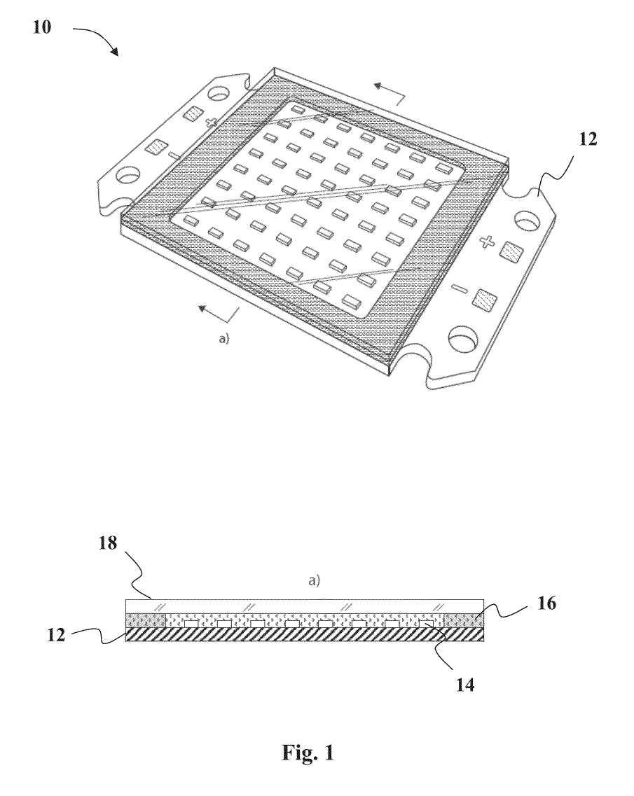

FIG. 1 shows an example component 10. The component has a substrate 12 having a plurality of LED's 14 mounted on the substrate. Additionally there is a spacer 16 which is mounted on the substrate and surrounding the plurality of LED's. The spacer 16 has a height which is greater than that of the LED's such that a transparent covering 18 can be mounted on top of the spacer and not come in contact directly with any of the LED's.

The spacer 16 can thus be hermetically sealed to a first surface of the substrate and to the transparent covering. The hermetically sealed space containing the light emitter component(s), can be defined as the space between the substrate, the spacer and the transparent covering. According to certain embodiments it is beneficial for the hermetically sealed space to be essentially in a vacuum. In particular, the pressure can be between, for example, 0.1 mTorr to 100 mTorr.

The hermetically sealed space can be at least partially filled with a gas. Depending on the application and device requirements the gas can be, for example, N², O² or other inert gas such as noble gas element. The gas composition and pressure can be tuned to fit the application needs. The cavity can be filled with suitable dielectric liquid to provide additional protection against moisture or functionality such as cooling of the active units in the cavity. The cavity can also be filled with a wavelength conversion material such as phosphor gel. Another possibility is to apply gettering materials in the cavity together with one or more of the aforementioned material fillings and atmospheres.

The light emitter component can be mounted directly on a first surface of the substrate as shown, for example, in FIG. 1. However, other constructions and layers can be disposed between the light emitter component and a substrate. For example, the substrate 12 could be a primary heat sink composed of a highly thermally conductive material, for instance a metal. The light emitter components can then be mounted on a dielectric material which at least partially covers the substrate. Similarly, the substrate could be multi-layered or merely a dielectric material. Furthermore, the substrate, or a portion of the substrate may contain electrical connections. An example would be the positive and negative terminals shown in the figures.

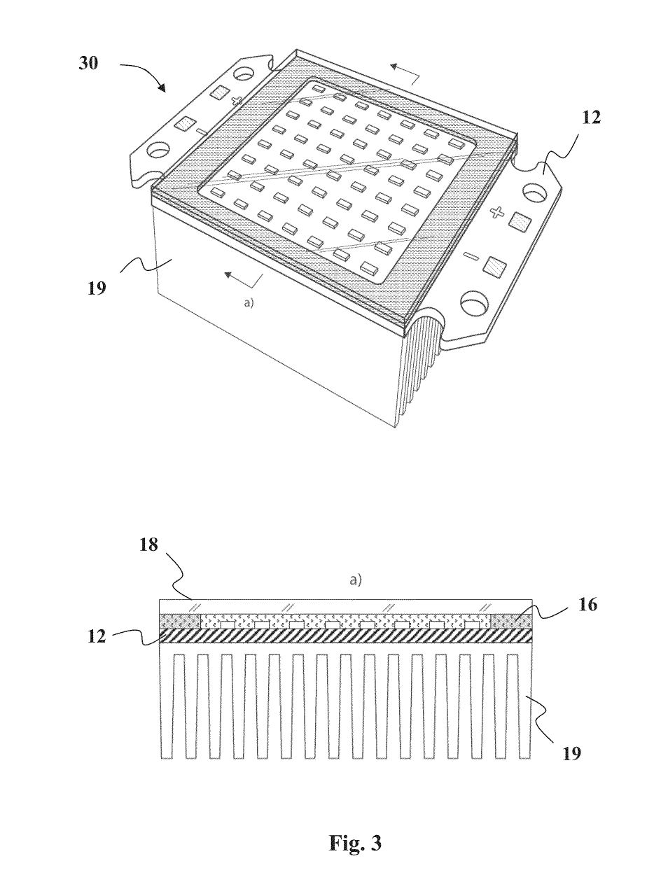

As discussed above, the substrate may contain, be comprised of or even consist of at least one heat sink. The substrate may be a heat sink itself or may include a heat sink and/or secondary heat sink. FIG. 3 shows an example 30 of the component 10 of FIG. 1 which has a heat sink 19 comprising a plurality of fins mounted on the opposite surface of the substrate from the light emitting components. Accordingly, according to certain embodiments the substrate comprises a first surface which is a dielectric material which is arranged directly on top of a heat sink. Additionally, the first surface of the substrate may be discontinuous and the light emitter component can be mounted directly to the heat sink.

FIGS. 1 and 3 show an example of a component having a spacer which is rectangular, or square. Additionally, the component is arranged such that there is little or no overhang of substrate on at least two sides of the component. Arrays of light emitting components can be arranged on the substrate and then surrounded with a spacer geometry which minimizes the component size.

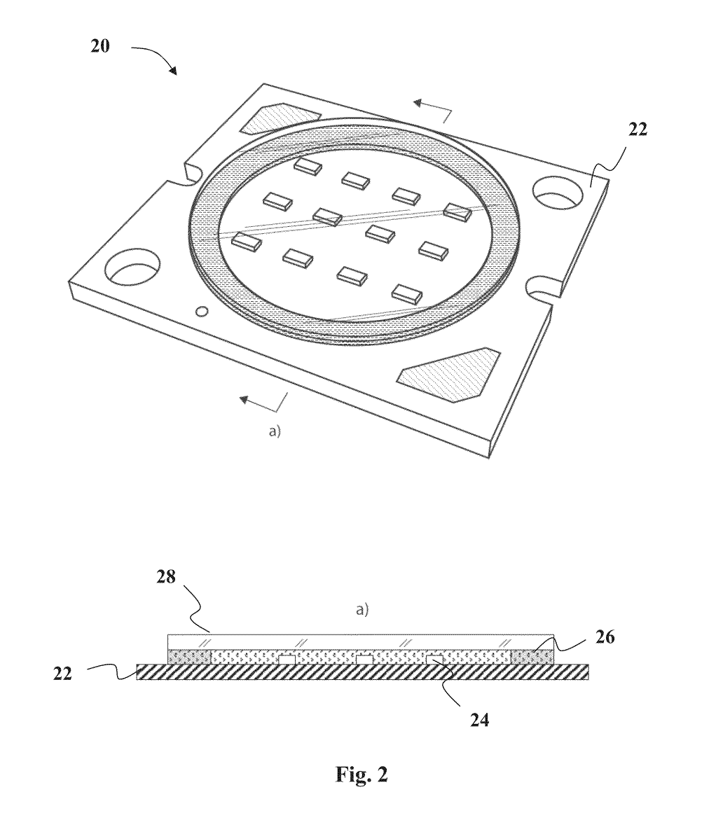

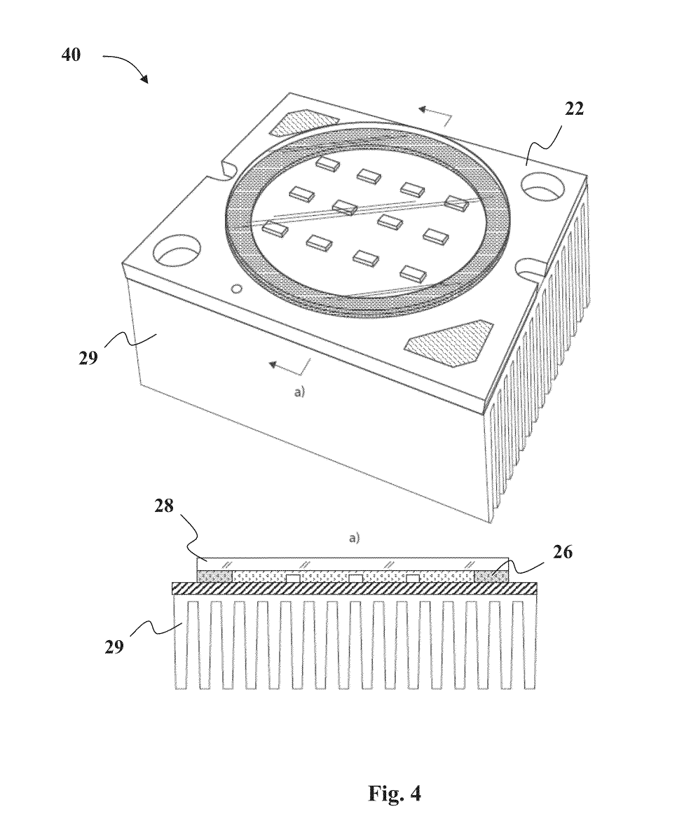

FIGS. 2 and 4 show examples 20 and 40 respectively of a component 20 having a spacer 26 which is circular, or ovular, in geometry. The substrate 22 in the present examples extends past the spacer on all sides. A benefit of such a geometry is realized if the substrate 22 is a primary heat sink, or other heat sink. The added surface area thus helps in the dissipation of heat. It also allows for greater area on the opposite surface of the substrate from the light emitter components for a heat sink 29 having a greater size. Similar to the previous examples, the transparent covering 28 has a shape generally similar to the outer perimeter of the spacer geometry.

Regarding any of the examples, the spacer can be a glass frit, metallic spacer or conductive glass spacer. Additionally, those of ordinary skill will recognize other spacer materials which can be used with regards to the present invention. Similarly, one of ordinary skill in the art will recognize countless alternative geometries and combinations of geometries for the substrate, spacer and transparent coverings. Though generally rectangular substrates and generally similar sized spacer/transparent covering combinations are preferable, variations do not depart from the scope of the present invention.

Furthermore, while it is an aspect of certain embodiments of the present invention to provide a hermetically sealed cavity for the light emitter components, it is possible to have a discontinuous spacer which would comprise at least one gap allowing for the atmosphere within the cavity to be substantially equal to the surrounding atmosphere of the component.

Additionally, there is herein disclosed means to include a Wavelength Conversion (WLC) layer which does not need to be directly in contact with the heat dissipating unit itself. Such an approach is preferable in order to avoid problems related to the mismatch of thermal expansion coefficients of different materials. The presented encapsulation scheme allows for greater freedom with respect to the WLC materials which can be applied as the WLC material is not directly in contact with the heat dissipating unit or a high temperature chip.

For example, the wavelength conversion layer can be physically separated from the high temperature part of the components, e.g. a LED chip(s). The hermetic sealing capability of, for instance, a glass-frit technique provides protection to sensitive wavelength conversion materials as well. This helps with the avoidance of degradation due to moisture or corrosive components in ambient atmosphere.

The transparent covering can be, but is not limited to a visible light transparent covering. Embodiments of the present invention are particularly useful for implementations where the light emitter used in the component does not emit visible light. Therefore, the transparent covering should be transparent to the electromagnetic radiation emission of the light emitter which is desired to pass through the covering.

The transparent covering can be made of quartz, glass, sapphire, acrylic, polycarbonate, Mylar, polyester, polyethene, composites thereof, or other material which is transparent to the electromagnetic radiation originating from the emitter or impinging on the component. The material for the transparent covering should be matched with the thermal expansion coefficients of the underlying spacer structure to avoid reliability issues under thermal stress, for example in form of heating-cooling cycles while the device is in typical operation or storage.

Separate manufacturing of the transparent covering allows for low-cost and efficient fabrication of functional features on the covering itself. For example a wavelength conversion layer, electrical and/or optical structures can be applied and fabricated on the same physical transparent covering. The wavelength conversion layer can be easily manufactured, for example by applying silk printing method. An example of wavelength conversion materials are red phosphors.

It is advantageous to produce LED lamp and luminaires with high color rendering index (CRI), general lighting devices comprising high R₉ value or R₉ value higher than 50 and in general white light lamps and luminaires rich with 600-800 nm emission from red light emitting phosphors.

However there are several applications beyond general lighting. Therefore, an optimal emission spectrum LED component is described which has particular advantage when used for living cells activation know for example as therapeutic, cell grow and metabolism activation, photosynthesis, photomorphogenesis due to a broad emission peak at 600 to 800 nm wavelength range. Human, animal and plant cells absorb efficiently in 600 to 800 nm wavelength range however different cells still have more selective yet relatively broad absorption bands in the given wavelength region. Due to the board emission peak of the LED COB component described by the innovation, the light energy is more efficiently transferred into the object. An embodiment of the innovation provides an LED COB component design to facilitate efficient generation of a broad emission peak at 600 to 800 nm wavelength range. Finally embodiments of the innovation provide a utilization of semiconductor quantum dots and nanoparticulate phosphor materials to obtain a preferable board emission peak at 600 to 800 nm wavelength range.

An LED device with a wavelength converter material of the partial- or complete-conversion of the LED's electroluminescence may contain a supplementary phosphor which absorbs a portion of the emission with a wavelength shorter than 500 nm and emits red/far-red light in the spectral range of 600 to 800 nm, which meets the photosynthetic and photomorphogenetic needs of plants. Such a phosphor can be an oxide, halooxide, chalcogenide, nitride or oxynitride compound activated by ions of divalent or tetravalent manganese, divalent or trivalent europium, trivalent bismuth, or divalent tin.

For example, the supplementary red component can be generated in inorganic phosphors, such as but not limited to: Mg₂SiO₄:Mn²⁺; Mg₄(F)GeO₆:Mn²⁺; (Mg,Zn)₃(PO)₄:Mn²⁺; Y₃Al₅O₁₂Mn⁴⁺; (Ca,Sr,Ba)₂Si₅N₈:Eu²⁺; Sr₂Si₄AlON₇IEu²⁺; MgO—MgF₂—GeO₂Eu²⁺; Y₂O₂S:Eu³⁺,Bi³⁺; YVO₄:Eu³⁺,Bi³⁺; Y₂O₃:Eu³⁺,Bi³⁺; SrY₂S₄Eu²⁺SrS:Eu²⁺; MgSr₅(PO)₄:Sn²⁺; (Ca):SiN₂:Ce²⁺; (Ca,Sr)SiN₂:Eu²⁺; (Ca,Ba)SiN₂,AlO:Eu²⁺; (Ca,Sr,Ba)₂Si₅N₈:Eu²⁺; Gd₃Ga₅O Cr³⁺; (Ca,Sr,Ba)₂Si₅N₈:Eu²⁺ and Gd₃Ga₅O₁₂:Cr³⁺.

However all wavelength conversion materials are subject to thermal quenching in some degree and in particularly long stokes shift phosphor wavelength conversion materials are susceptible to thermal quenching of conversion efficiency. Here in particular long stokes shift is considered to be more than 150 nm wavelength shift from a blue emission peak emission to red or far red wavelength region.

As with common LED devices the phosphor material is located in close proximity to the semiconductor diode, such as an InGaN chip. Therefore the phosphorous material is subject to heat produced by the semiconductor chip and resulting in non-radiative recombination. Phosphorous materials are also subject to self-heating, meaning that part of the emission from the semiconductor diode chip is absorbed by the phosphor and transformed into heat in the material. Self-heating is further increased when phosphor particles are densely packed particles and cause a lot of scattering of the diode chip emitted light. Thus, part of the scattered light energy coverts to heat, which lowers the conversion efficiency. In order to avoid thermal quenching and self-heating quenching derived conversion efficiency decrease in LED devices a novel LED component was designed. In particular the design addresses use of light conversion materials with wavelength stokes shift more than 150 nm. A more detailed description of the design with relation to the location of the WCL can be found in U.S. 61/698,591 which is herein incorporated by reference.

Single or multiple wavelength conversion materials can be mixed or geometrically fabricated, for instance, on the bottom surface of the transparent covering. The wavelength conversion materials can be easily patterned to form desired performance and allow attachment of the transparent covering to the spacer layer on top of the substrate. It is understood that the wavelength conversion layer could also be manufactured on the top surface of the transparent covering or within the transparent covering itself.

Furthermore, additional features can be manufactured on, or within, the transparent covering. Examples are optical fiducials to ease in the manufacturing and alignment of the transparent covering to the spacer layer on top of the substrate. Additionally, electrical structures can be formed on the top or bottom surfaces of, or within, the transparent covering to provide additional functionality and allowing for example the formation of smart modules or smart light engines.

The transparent covering can further serve as a mounting area for various types of electronic components. Electrical functions can be made possible by processing electrical conductors on the transparent covering. Such electronic components could consist or comprise of, for example, detectors for temperature, proximity, contact, touching, pressure, light intensity or humidity. Said conductors can be made of metal and/or thin layers of conductive transparent glass, such as TiO2 thin films.

An anti-reflection (AR) coating to prevent transmission losses can be used as an optical structure. AR coatings are highly beneficial with regards to reducing losses, for example in the cases of applying light emitting components on the top of the substrate. Other types of multilayer optical filtering structures can be fabricated on the top or bottom surface, or within of the transparent covering.

The transparent covering can comprise focusing and light collecting structures such as lenses and/or mirrors. Such structures can be of a refractive or diffractive nature and can increase the overall efficiency of, for instance, an LED module or enhance the light collection efficiency in case of a detector module. Such optical structures can be of a refractive or refraction nature and can be fabricated with, for example, molding, engraving, blazing, etching or embossing or other convenient method, either on the top or bottom surface, or within the transparent covering.

According to certain embodiments the transparent covering contains an optical structure comprising at least two layers of transparent material. The transparent cover can also comprise at least one optical structure which prevents light from the light emitter component from being reflected back to the substrate, in particular which prevents at least 85%, preferably at least 90%, more preferably at least 95% of the light from the light emitter component from being reflected back to the substrate. The transparent covering may contain, comprise or consist of at least one additional type of optical structure.

Glass-frit technology can be applied for optoelectronics packaging by mounting singulated active units, such as LEDs, into a ceramic carrier. The ceramic carrier forms the base for the module. Such ceramic substrates can be made of, for example, Aluminum nitride (AlN) or Aluminum oxide (Al2O3). Glass-fits are less sensitive to surface roughness and the topography of the substrate and transparent covering compared to other methods, such as fusion bonding or eutectic bonding.

The glass-fit technique provides a flexible method to package active units on a common substrate. Because the glass-frit technique is flexible in creating the actual spacer without any fixed mask set, changing the number of units and packaging geometry is easy and not limited by fixed accessories of the process.

Similarly the packaging concept allows different chip sizes to be included in a cavity without any difficulties in the glass-frit deposition. The size of a module is only limited by available equipment and its ability to deposit the glass-fit powder or preform on a very large substrate, e.g. larger than 100 mm² or longer than 200 mm. Additionally, the volume of the cavity can easily be adjusted by tuning the deposition height of the spacer layer, i.e. the glass-fit or preform material thickness. Particularly, the flexibility to apply any cavity filling or create any desired ambient cavity is of importance from the application point of view.

While some glass-frit techniques have long been in use it has only recently advanced as a lead-free technique. Previously, glass-fit technology required temperatures which were too high to be applied directly for use with, for example, LED chip encapsulation. A low glass melting temperature, e.g. <300° C., is required to be able to apply this method with active electronic chips mounted on a substrate. Typically, the maximum temperature electronic chips can withstand without causing damage is below 350° C. For example, InGaN LED chips can only typically withstand about 300-325° C. depending on the exact semiconductor stack structure and chip geometry.

The basic substrate can easily be tailored for a chosen application and can contain active units of different kind For high power applications where the active units, such as LED emitters, dissipate heat in excess of 1 W/1 mm² in active areas, an efficient heat sinking is desired.

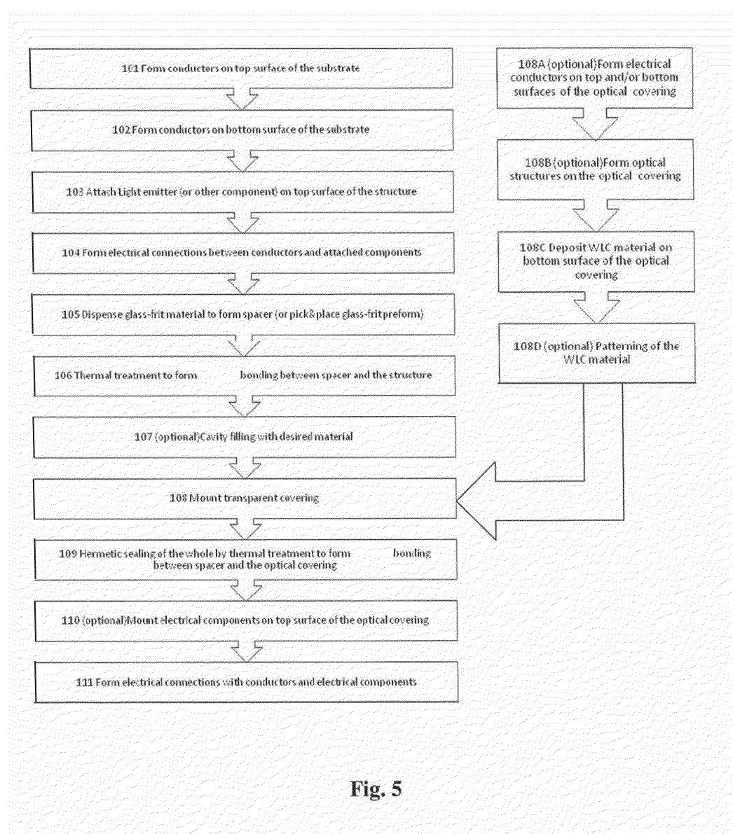

Regarding FIG. 5, a simplified flow diagram of an example method of manufacturing of a component is shown. An encapsulation process begins with a step 101 to form conductors and the desired layout on a top surface of a substrate. Such layout is designed to allow the mounting of LED chips. The method can also be accomplished by forming conductors on one or more additional surfaces or portions of surfaces of the substrate. Furthermore, in a layered substrate, conductors can be formed within the substrate itself.

In step 102 conductors are formed on the bottom surface of the substrate. In this step the conductors can be formed on the bottom surface of a substrate together with vias to make electrical connections from the top surface conductors to the bottom surface conductors. These bottom surface conductors are generally to allow electrical connections to be made to external circuitry, such as an electrical power source or control unit. Similarly to step 101 above, conductors may be formed on one or more additional surfaces or portions of surfaces of the substrate. Furthermore, in a layered substrate, conductors can be formed within the substrate itself. Additionally, steps 101 and 102 can be reversed or carried out substantially simultaneously.

In step 103 active units, for example such as LED emitters, are mounted and attached on top surface of the structure. Next 104 electrical connections are formed between the active units and the conductors on the top surface of the structure.

In step 105 a solder preform, for example a glass solder preform, is printed or paste deposited on the substrate. The preform is placed on the substrate to form the desired geometry and cavity size on the top surface of the structure. In the case of a glass-fit preform, a pick and place machine can be used for the preform mounting. In the next step 106 the whole structure with the mounted active units and mounted spacer will go through a thermal treatment to allow prebonding of the structure and the spacer.

In step 107, which may be an optional step in certain embodiments, the cavity can be filled with a desired material(s). Subsequently 108 the prepared transparent covering is mounted on top of the spacer so that the bottom surface of the transparent covering is facing the spacer. In step 109 the hermetic sealing of the whole structure is done by means of a thermal treatment. The process of steps 101-109 should be performed in an appropriate environment and atmosphere to prevent outside contamination during the encapsulation.

A high strength bonding is thus formed between the structure and the spacer, and between the spacer and the transparent covering. In optional step 110, electrical components can be mounted on the top surface of the transparent covering. Additionally, 111, electrical connections are optionally formed with the electrical components and the conductors on top surface of the transparent covering. It is understood that the mounting of electrical components on top surface of the transparent covering can also be made prior the mounting of the transparent covering to the spacer or at another time in the manufacturing process.

The transparent covering is prepared separately and prior to its mounting on the spacer. In a first (optional) step 108A electrical conductors are formed on the top and/or bottom surface of the transparent covering. Optionally, in step 108B any optical structures can be formed on the transparent covering. Next 108C the WLC material is manufactured on the bottom surface of the transparent covering. Optionally 108D the WLC material layer can be patterned before proceeding to the mounting of the transparent covering to the spacer and the structure.

While the present method has been described with reference to a top surface of a substrate and placing or forming elements on said surface, the top surface may not be a single finite layer. For instance, the substrate may comprise a plurality of layers and the top layer or layers may be discontinuous. Therefore, one step may form conductors on one material layer on the top of the substrate and the light emitter components and/or spacer may be placed on a different material or layer on the top or top portion of the substrate. Such designs do not depart from the scope of the present invention. The present discussion relates to the bottom surface of the substrate and other similar instances in the design and manufacturing as well.

The substrate, transparent covering, and sealing materials used should be leak free. Additionally, they should not produce any out-gassing during the assembly process or during the storage or operation of the final component. It is preferable for certain embodiments to include a bake-out assembly phase in a high vacuum to ensure degassing and to remove any residual gasses in the used materials.

The cavity can be filled in the process with suitable inert gas. A preferred phase is between steps 105 to 109. Depending on the application and device requirements the atmosphere can be N², O² or other inert gas such as noble gas element. Gas composition and pressure can be tuned to fit the application needs. The cavity can be filled with suitable dielectric liquid to provide additional protection against moisture or functionality such as cooling of the active units in the cavity. The cavity can also be filled with a wavelength conversion material such as phosphor gel. Another possibility is to apply gettering materials in the cavity together with one or more of the aforementioned material fillings and atmospheres.

The present invention is limited to applying glass-frit methods with glass powders or glass preforms. Metallic preforms, metal powders, or conductive glass materials can be applied as well, in place of commonly used glass-frit preforms and materials such as Bi—Zn—B compositions.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. An optoelectronic component comprising;
a substrate,
at least one light emitter component mounted on the substrate,
a spacer, affixed to a first surface of the substrate and surrounding the light emitter component, said spacer having a height greater than the light emitter component, and
a transparent covering affixed to the spacer opposite the substrate.

2. The optoelectronic component according to claim 1, wherein the spacer is hermetically sealed to the first surface of the substrate and to the transparent covering.

3. The optoelectronic component according to claim 1, further comprising a hermetically sealed space containing the light emitter component, said hermetically sealed space defined by the substrate, the spacer and the transparent covering.

4. The optoelectronic component according to claim 3, wherein said hermetically sealed space is essentially in a vacuum wherein the pressure is between 0.1 mTorr to 100 mTorr.

5. The optoelectronic component according to claim 3, wherein said hermetically sealed space is at least partially filled with a gas.

6. (canceled)

7. The optoelectronic component according to claim 1, wherein the light emitter component is mounted on the first surface of the substrate.

8. (canceled)

9. The optoelectronic component according to claim 1, wherein the substrate contains at least one heat sink.

10. The optoelectronic component according to claim 1, wherein the substrate comprises a first surface which is a dielectric material arranged directly on top of a heat sink.

11. The optoelectronic component according to claim 10, wherein the first surface is discontinuous and the light emitter component is mounted directly to the heat sink.

12. The optoelectronic component according to claim 1, wherein the spacer is a glass frit, metallic spacer or conductive glass spacer.

13. The optoelectronic component according to claim 1, wherein the transparent covering contains an optical structure comprising at least two layers of transparent material.

14. (canceled)

15. (canceled)

16. (canceled)

17. The optoelectronic component according to claim 1, wherein the transparent covering comprises a wavelength conversion material.

18. (canceled)

19. The optoelectronic component according to claim 1, wherein at least one of the light emitter components comprises an In-, Ga-, and/or N-containing compound.

20. The optoelectronic component according to claim 1, wherein at least one of the light emitter components is selected from the group of red light emitters, near infrared (NIR) light emitters and InGaN light emitters.

21. (canceled)

22. (canceled)

23. The optoelectronic component according to claim 1, wherein the spacer has a continuous geometric shape surrounding an arrangement of a plurality of light emitter elements.

24. (canceled)

25. (canceled)

26. (canceled)

27. The optoelectronic component according to claim 1, wherein the transparent cover is transparent to electro-magnetic radiation emitted by the light emitter and/or visible light.

28. (canceled)

29. The optoelectronic component according to claim 1, wherein the spacer is mounted on the transparent covering prior to being mounted on the first surface of the substrate.

30. The optoelectronic component according to claim 1, wherein the spacer at least semi-hermetically seals the space between the covering and substrate containing the at least one light emitter

31. (canceled)

32. (canceled)

33. (canceled)

34. (canceled)

35. (canceled)

36. (canceled)

37. (canceled)

38. A method of manufacturing an optoelectronic component comprising the steps of;
attaching at least one light emitter component to the substrate,
dispensing a spacer material on top of the substrate surrounding the at least one light emitter component,
mounting a transparent covering on the spacer, and
hermetically sealing the spacer to the transparent covering and substrate by thermally treating the composition in order to form a bonding between at least the spacer and the transparent covering at a temperature below which would damage the at least one light emitter component.

39. The method of manufacturing an optoelectronic component according to claim 38, further comprising the step of thermally treating the substrate and spacer material prior to mounting the transparent covering to form a high strength bond between the substrate and spacer, wherein the thermal treating is not great enough to damage the at least one light emitter component.

40. (canceled)

41. (canceled)

42. (canceled)

43. (canceled)
